(19) United States
(12) Patent Application Publication
(10) Pub. No.: US 2017/0253970 A1
(43) Pub. Date: Sep. 7, 2017

(54) ALD Coating System and Method for Operating an ALD Coating System

(71) Applicant: OSRAM OLED GmbH, Regensburg (DE)

(72) Inventors: Michael Popp, Freising (DE); Richard Baisl, Regensburg (DE)

(21) Appl. No.: 15/599,338

(22) Filed: May 18, 2017

Related U.S. Application Data
(62) Division of application No. 14/603,698, filed on Jan. 23, 2015.

(30) Foreign Application Priority Data
Jan. 24, 2014 (DE) 10 2014 100 832.4

(51) Int. Cl. C23C 16/455

(52) U.S. Cl. CPC C23C 16/45544; C23C 16/45561

(57) ABSTRACT

A method for operating an ALD coating system is disclosed. In an embodiment the method includes lowering a temperature of an intermediate container by a device for cooling the intermediate container so that a temperature of the intermediate container is below a temperature of a storage container, flowing a partial amount of the organometallic starting material into the intermediate container, heating the partial amount of the organometallic starting material by a device for heating the organometallic starting material so that a pressure of the partial amount of the organometallic starting material is constant over time and/or is greater than a pressure of the organometallic starting material in the storage container and opening a second multiway valve so that the partial amount of the organometallic starting material partially flows as a gas into a process chamber.

This is a divisional application of U.S. application Ser. No. 14/603,698, entitled “ALD Coating System and Method for Operating an ALD Coating System” which was filed on Jan. 23, 2015, and claims priority to German patent application 10 2014 100 832.4 filed on Jan. 24, 2014, both of which are incorporated herein by reference.

### TECHNICAL FIELD

An ALD coating system and a method for operating an ALD coating system are provided.

### SUMMARY

Embodiments of the invention provide an ALD coating system and a method for operating an ALD coating system that are cost-efficient.

According to at least one embodiment, the ALD coating system comprises a storage container for an organometallic starting material. The ALD coating system (atomic layer deposition, ALD) may be intended for depositing thin layers, in particular atomic layers or monolayers, by self-limiting surface reactions. The self-limiting surface reactions can be particularly attributed here to the organometallic starting material.

“Organometallic starting material,” also referred to as a precursor, is understood in the present context as meaning a reactive substance that may be in a liquid, solid and/or gaseous phase and, in particular, ideally does not react with itself or ligands of itself. For example, at high temperatures or under a pressure that occurs at high temperatures, the organometallic starting material may decompose into disintegration products or decomposition products.

“High temperatures” is understood in the present context as meaning a temperature that is higher than the temperature of the storage container.

The organometallic starting material may be particularly suitable for the depositing of a thin-film encapsulation on an optoelectronic organic component. The thin-film encapsulation is used in particular for hermetically sealing a light-emitting organic semiconductor layer sequence of the optoelectronic organic component. The thin-film encapsulation may particularly comprise one or more layers that are produced by means of the ALD method.

The storage container may in particular be pressure-stable. The storage container comprises or consists of a material that may in particular have a high thermal conductivity. The storage container is particularly suitable for storing the organometallic material at a constant temperature. The storage container is, for example, at a temperature at which particularly preferably no decomposition products or disintegration products of the organometallic starting material form. The storage container is in particular closed off with respect to the surroundings.

According to at least one embodiment, the ALD coating system has an intermediate container for a partial amount of the organometallic starting material. The intermediate container may, for example, be pressure-stable and comprise a material or consist of a material that has a high thermal conductivity. The intermediate container is in particular closed off with respect to the surroundings.

“Partial amount” is understood in the present context as meaning in particular a subsidiary amount of the organometallic starting material from the storage container. For example, the partial amount of the organometallic starting material in the intermediate container is sufficient for depositing the monolayer for the thin-film encapsulation. The partial amount of the organometallic material enters the intermediate container in particular due to the vapor pressure of the organometallic starting material, it being possible for the feeding of the organometallic starting material into the intermediate container to be speeded up, for example, by a carrier gas, for example, an inert carrier gas.

The partial amount may, for example, have a weight of at least 0.5 mg to at most 1 kg.

According to at least one embodiment, the intermediate container has a device for heating up the organometallic starting material. The device may, for example, increase the temperature of the intermediate container and/or the temperature of the organometallic starting material itself. The device may in particular be capable of warming and/or heating the organometallic starting material by radiation, electromagnetic fields and/or plasma. In other words, the intermediate container comprises variable vapor pressure control. In dependence on its temperature, the organometallic starting material has the corresponding vapor pressure. The vapor pressure of the organometallic starting material may, for example, double each time there is an increase in the temperature of the starting material of 10° C. The intermediate container is used in particular as an intermediate store, first at a low vapor pressure of the organometallic starting material, for receiving the partial amount at first at a low vapor pressure, and then, after heating up, at an increased pressure for discharging very quickly in a pulse-like or surge-like manner. This results in a reduction of a corresponding pulse time at a higher depositing rate. “Pulse-like” is understood in the present context as meaning feeding, carried out within a time interval, of the organometallic starting material into a further chamber that is connected to the intermediate chamber by way of a line, no feeding of the organometallic starting material being able to take place between the time intervals. Furthermore, the pulse-like feeding of the organometallic starting material may be realized, for example, by opening and closing one or more multiway valves of the ALD coating system.

According to at least one embodiment, the intermediate container is arranged downstream of the storage container by way of a first multiway valve. In a direction of flow of the organometallic starting material taken from the storage container, the intermediate container may be arranged downstream of the storage container. The intermediate container may in particular be connected to the storage container by way of a line.

“Line” is understood in the present context as meaning a pipe or pipeline that is designed for transporting the organometallic starting material. The lines particularly connect individual components of the ALD coating system to one another. The length of the line between the storage container and the intermediate container may, for example, be at least 1 m, for example, at least several meters, in particular 10 m or more. For example, siting the storage container in the foundation of a production line is prescribed on the basis of safety regulations.

The first multiway valve is located, for example, in the line between the storage container and the intermediate chamber. The first multiway valve can be used in particular for controlling and/or regulating an inflow of the organometallic starting material from the storage container into the intermediate container, for example, by opening and closing the first multiway valve.

According to at least one embodiment, the intermediate container is connected to a process chamber by way of a second multiway valve and to a collecting chamber by way of a third multiway valve. The intermediate container has in particular two lines extending from it, having either the second multiway valve or the third multiway valve. The second and third multiway valves particularly allow that undesired decomposition products or disintegration products of the organometallic starting material can be prevented from entering the process chamber. This can be achieved in particular by organometallic starting material, which is particularly preferably in the gaseous state of aggregation, being fed to the process chamber by opening the second multiway valve, the third multiway valve remaining closed. The disintegration products or decomposition products that form during heating up are, for example, pumped away by opening the third multiway valve, the second multiway valve remaining closed. This is possible in particular because the disintegration products or decomposition products have a vapor pressure that is different from the vapor pressure of the gaseous organometallic starting material.

According to at least one embodiment, the ALD coating system comprises a storage container for an organometallic starting material and an intermediate container for a partial amount of the organometallic starting material, the intermediate container having a device for heating up the organometallic starting material. The intermediate container is arranged downstream of the storage container by way of a first multiway valve and the intermediate container is connected to a process chamber by way of a second multiway valve and to a collecting chamber by way of a third multiway valve.

For depositing a thin-film encapsulation for optoelectronic organic components by means of an ALD coating system, organometallic starting materials in temperature-stabilized storage containers are fed by pulse-like opening of a multiway valve of the storage container to a gas stream that carries the organometallic starting material to the process chamber or conducts it directly to a process chamber. Depending on the vapor pressure of the organometallic starting material, which is fixed by the temperature of the organometallic starting material, an appropriate amount of the organometallic material reaches the gas stream. This gas stream is also influenced by the conductance of corresponding lines and injector nozzles used of the ALD coating system. Particularly temperature-sensitive organometallic starting materials, for example, TBMAZ (tetrakis(dimethylamino) zirconium) for depositing ZrOx, cannot be heated up here at will, since at high temperatures they form disintegration products or decomposition products.

There is consequently the problem that, owing to the low temperature or the low vapor pressure of the organometallic starting material, the depositing of a layer (monolayer) necessitates disproportionately long process times, with pulse lengths of, for example, a minute, to deposit a single monolayer.

The ALD coating system described here provides a way in which temperature-sensitive organometallic starting materials can be used in commercial and technical respects in ALD coating systems, on the one hand making it possible to use long conductance-limiting feed lines between the storage container and the intermediate container that are advantageous in terms of safety. This is advantageous in particular because the organometallic starting material described here is highly flammable and, for example, in contact with water, in particular moisture from the air, breaks down with a violent reaction. Furthermore, the organometallic starting material described here may be extremely harmful to the respiratory tract and caustic when it comes into contact with the skin and eyes. In addition, symptoms such as coughing, shortness of breath, headache, nausea and vomiting may occur. With the coating system described here, storage of the organometallic starting material in the storage container may advantageously take place in the foundation of a production line, only the amount of the organometallic starting material that is required for depositing the monolayer being made available in the intermediate container.

The ALD coating system described here on the other hand makes use of the idea of for example providing the partial amount of the organometallic starting material that is required for a monolayer, in particular close to the process chamber, by the use of an intermediate container. For this purpose, initially a partial amount of the organometallic starting material, which initially has a low vapor pressure, is conducted from the storage container into the intermediate container at low vapor pressure. The partial amount that is required for a coating cycle (run) is then heated up by a device in the intermediate container and then discharged very quickly at increased vapor pressure, which means a reduction of the pulse time with a higher depositing rate. A residual amount of the organometallic starting material in the intermediate container that remains after the coating cycle is then removed and/or extracted by suction from the intermediate container by a cleaning cycle or venting cycle (venting). This is combined with what are known as running/venting operations as a coating and cleaning cycle for the intermediate container, for removing the disintegration products before and/or after the coating cycle. For example, the running/venting operation is also possible during breaks in the coating of the ALD coating system. The ALD coating system described here particularly allows temperature-critical organometallic starting materials, such as, for example, TDMAZ, to be used from commercial and technical aspects.

Furthermore, particularly preferably, no material degradation of temperature-sensitive organometallic starting materials takes place in the ALD coating system described here, even when there are high rates of consumption and amounts of removal, since, particularly preferably, only the partial amount that is required for a coating cycle is heated up. The running/venting operation allows the ALD coating system to be adapted to different cycle rates of multi-plate systems.

According to at least one embodiment, the intermediate container has a device for cooling down the intermediate container. The device is capable in particular of lowering the temperature of the intermediate container in such a way that the temperature of the intermediate container is lower than the temperature of the storage container. The difference in temperature forming between the storage container and the intermediate container can in particular speed up an inflow of the organometallic starting material into the intermediate container, since, because of the difference in temperature, a difference in pressure can also prevail between the intermediate container and the storage container. The organometallic starting material may for example condense on inner wall surfaces of the intermediate container.

There follows a description of a method for operating an ALD coating system for growing at least one layer on a substrate according to one of the preceding embodiments of the ALD coating system. All of the features described for the ALD coating system are disclosed for the method, and vice versa.

According to at least one embodiment of the method, the organometallic starting material is provided in the storage container. The organometallic starting material decomposes, for example, at high temperatures. The organometallic starting material may be particularly intended for depositing the thin-film encapsulation in the process chamber.

According to at least one embodiment of the method, the partial amount of the organometallic starting material flows into the intermediate container. The organometallic starting material flows out of the storage container into the intermediate container until the required and/or desired partial amount of the organometallic starting material, for example, for the monolayer, is in the intermediate container.

According to at least one embodiment of the method, the partial amount of the organometallic starting material is heated up by the device for heating up the organometallic starting material, so that a pressure of the partial amount of the organometallic starting material that is constant over time and is greater than a pressure of the organometallic starting material in the storage container is established. “Constant over time” is understood in the present context as meaning that, within the limits of a measuring tolerance, the vapor pressure in the intermediate container is kept stable, uniform and/or with little fluctuation about a mean value of the vapor pressure.

According to at least one embodiment of the method, the second multiway valve opens when the pressure that is constant over time occurs, and the partial amount of the organometallic starting material partially flows as a gas into the process chamber in a pulse-like manner. In a next step, the pulse-like inflow of the gaseous organometallic starting material is followed by the second multiway valve being closed and the third multiway valve being opened, and the organometallic starting material that remains in the intermediate container flowing away into the collecting chamber.

According to at least one embodiment for operating an ALD coating system for growing at least one layer on a substrate, the method comprises the following steps:
providing the organometallic starting material in the storage container,
flowing of the partial amount of the organometallic starting material into the intermediate container,
heating up the partial amount of the organometallic starting material by the device for heating up the organometallic starting material, so that a pressure of the partial amount of the organometallic starting material that is constant over time and is greater than a pressure of the organometallic starting material in the storage container occurs,
   the second multiway valve opening when the pressure that is constant over time occurs, and the partial amount of the organometallic starting material partially flowing as a gas into the process chamber in a pulse-like manner, the pulse-like inflow being followed by the second multiway valve closing, the third multiway valve opening, and the organometallic starting material that remains in the intermediate container flowing away into the collecting chamber.

According to at least one embodiment of the method, before the heating up of the partial amount of the organometallic starting material, a temperature of the intermediate container is lowered by the device for cooling down the intermediate container. This allows the difference in pressure between the storage container and the intermediate container to be increased in such a way that the inflow of the organometallic starting material into the intermediate container is speeded up.

The embodiments described below apply to the ALD coating system described here and also to the method described here.

According to at least one embodiment, a conductance of the line between the intermediate container and the process chamber is constant or largely constant. “Constant” is understood in the present context as meaning that there is no difference in pressure between the ends of the lines. “Largely constant” is understood in the present context as meaning the difference in pressure between the ends of the lines that may be less than or equal to 10%. Preferably, the difference in pressure is less than or equal to 5%, particularly preferably less than or equal to 3%.

In the present case, the conductance is the reciprocal value of the flow resistance. When the organometallic starting material, for example, gaseous organometallic starting material, flows through the line, a pressure differential occurs at the ends of the lines, in particular in dependence on a line length. For example, the conductance can be kept constant or largely constant by a correspondingly short line length between two containers of the ALD coating system.

According to at least one embodiment, the conductance of the line between the first multiway valve and the intermediate container is constant or largely constant. In particular, the vapor pressure of the organometallic starting material in the intermediate container can be kept constant or largely constant during the opening and closing of the first multiway valve by the line between the first multiway valve and the intermediate container. That is to say that the line located between the first multiway valve and the intermediate container may have been formed so as to be short enough that, particularly preferably, no difference in pressure can be detected, for example, by a pressure gage, during the opening and closing of the first multiway valve.

According to at least one embodiment of the ALD coating system, a fourth multiway valve and a fifth multiway valve are arranged between the second multiway valve and the process chamber, the second multiway valve and the fourth multiway valve being located on the same line to the process chamber, taken from the intermediate container, and the fourth multiway valve being arranged downstream of the second multiway valve. The fifth multiway valve is located on the line between the second multiway valve and the fourth multiway valve. A gas-metering element for feeding a carrier gas and/or purging gas is arranged upstream of the fifth multiway valve.

By opening the second multiway valve, for example, the partial amount of the organometallic starting material from the intermediate container is at least partially directed further in the direction of the process chamber. In the line between the second multiway valve and the process chamber, the fourth multiway valve and the fifth multiway valve may be arranged in such a way that the pulse-like feeding of the organometallic starting material into the process chamber does not have to be controlled just by the switching of the second multiway valve alone. That is to say that pulse-like feeding of the organometallic starting material into the process chamber can be controlled by switching of the fourth or fifth multiway valve, without the second multiway valve having to be switched in the direction of the collecting chamber, that is to say having to be closed.

Furthermore, a carrier gas may be directed into the line to the process chamber by way of the line in which the fifth multiway valve is arranged. The carrier gas is used in particular for transporting the organometallic starting material that is in the gaseous phase. The supplying of the process chamber with the purging gas and/or the carrier gas may take place before, during and after the coating cycle.

According to at least one embodiment, the intermediate container comprises a multiplicity of individual intermediate chambers, the intermediate chambers respectively having the second multiway valve, the third multiway valve and a sixth multiway valve, and the sixth multiway valves being located between the first multiway valve and the intermediate chambers, taken from the storage container. The embodiment described here of the intermediate container allows multiple coating cycles to be carried out in a time-optimized manner, without allowance having to be made for a time for heating up the organometallic starting material in a single intermediate chamber. The number of intermediate chambers can, for example, dictate the number of coating cycles of the ALD coating system that are required for the thin-film encapsulation, without it being necessary to wait for the intermediate chamber to be filled and heated up in the meantime.

According to at least one embodiment, the intermediate chambers respectively have the device for heating up and the device for cooling down. This allows differences in pressure between the storage container and the individual intermediate chambers to occur, so that the inflow of the organometallic starting material into the intermediate chambers is speeded up.

According to at least one embodiment, the organometallic starting material in the storage container is free or largely free from disintegration products of the organometallic starting material. For this purpose, the organometallic starting material in the storage container is stored at a temperature at which demonstrably no disintegration products or decomposition products form.

According to at least one embodiment, the organometallic starting material in the process chamber is free or largely free from disintegration products of the organometallic starting material. The ALD coating system described here and the running/venting operations can have the effect that, after for example, one or more coating cycles, the process chamber in particular is kept free from disintegration products, that are produced in particular before the actual reaction, of the organometallic starting material.

According to at least one embodiment, arranged upstream of the storage container is a seventh multiway valve, for a further carrier gas. For example, the further carrier gas may speed up the inflow of the organometallic starting material into the intermediate container.

According to at least one embodiment, arranged upstream of the storage container is an eighth multiway valve, for cleaning the storage container. By opening the eighth multiway valve, it is possible in particular to feed into the storage container a purging gas, which can, for example, be used for cleaning the storage container.

According to at least one embodiment, the organometallic starting material is a tetrakis (dimethylamino)zirconium or a tetrakis(dimethylamino) hafnium (TBMAH) or a tetrakis(dimethylamino)tantalum (TBMAT) or some other organometallic compound.

According to at least one embodiment, the intermediate container has a pressure gage and/or arranged downstream of the collecting chamber is a vacuum pump. The pressure gage can be used in particular to check whether the required temperature or the required vapor pressure of the organometallic starting material is prevailing in the intermediate container. Disintegration products or decomposition products that have been directed from the intermediate container into the collecting chamber may, for example, be sucked away by the vacuum pump.

### BRIEF DESCRIPTION OF THE DRAWINGS

The ALD coating system described here and the method for operating an ALD coating system for growing at least one layer on a substrate are explained below on the basis of exemplary embodiments with associated FIGURES.

Elements that are the same, of the same type or act in the same way are provided with the same designations in the FIGURES. The FIGURES and the relative sizes of the elements represented in the FIGURES with respect to one another are not to be considered as true to scale. Rather, individual elements may be shown exaggerated in size for the sake of better representation and/or better understanding.

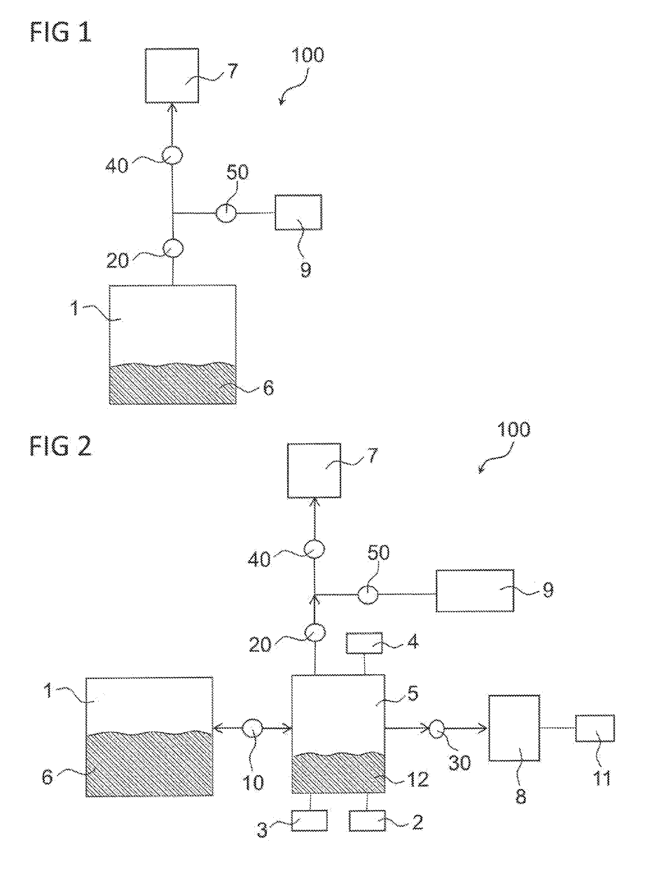

Exemplary embodiments of the ALD coating system described here and the method for operating the ALD coating system are explained in more detail on the basis of the schematic representations of FIGS. 1, 2, 3, 4 and 5.

### DETAILED DESCRIPTION OF ILLUSTRATIVE EMBODIMENTS

In the exemplary embodiment of FIG. 1, an ALD coating system 100 is schematically shown. The ALD coating system shown in FIG. 1 particularly does not comprise an intermediate container 5.

In the ALD coating system 100 of FIG. 1, an organometallic starting material 6 is stored in a storage container 1, in particular a temperature-stabilized storage container 1. The organometallic starting material 6 located in the storage container 1 may be stored at a temperature such that the organometallic starting material 6 does not form any disintegration products or decomposition products. In this case, the organometallic starting material 6 has a low vapor pressure. This has the consequence that a pulse-like inflow during a coating cycle is not possible and pulse times in the range of minutes are required for the production of a monolayer. In order to achieve quicker feeding into the process chamber 7, in particular a volume of the storage container 1 may be correspondingly increased, so that the surface of the organometallic starting material 6 in the storage container 1 correspondingly increases. However, such large storage containers 1 are not cost-effective.

In order to ensure a pulse-like inflow of the organometallic starting material into the process chamber 7, furthermore, the organometallic starting material 6 in the storage container 1 may be warmed or heated. This has the consequence that the organometallic starting material 6 has a high vapor pressure and the pulse-like inflow of the organometallic starting material 6 into the process chamber is possible. The pulse times required for this are in the range of milliseconds or seconds. However, the warming or heating of the organometallic starting material 6 leads to disintegration products or decomposition products of the organometallic starting material 6. This has the effect in particular that the organometallic starting material 6 in the storage container 1 at least partially cannot be used.

Furthermore, the exemplary embodiment of FIG. 1 does not have a collecting chamber 8, so that pumping away of the disintegration products or decomposition products from the storage container 1 is not possible. The organometallic starting substance 6 located in the storage container 1 is directed into the process chamber as a gas by way of a line in which there is a second multiway valve 20 and a fourth multiway valve 40, while between the second multiway valve 20 and the fourth multiway valve 40 there is connected a further line, which comprises a fifth multiway valve 50 and a gas-metering element 9 arranged downstream of the fifth multiway valve 50. The fifth multiway valve 50 is supplied with a purging gas and/or carrier gas by means of the gas-metering element 9.

Through the line, the gaseous starting material 6 of the storage container 1 is fed to a gas stream, which carries the organometallic starting material 6 to the process chamber 7, for example, by opening the second multiway valve 20 and the fourth multiway valve 40.

FIG. 2 shows an exemplary embodiment of an ALD coating system 100, which by contrast with the ALD coating system of FIG. 1 particularly has an intermediate container 5. The intermediate container 5 is arranged downstream of the storage container 1 by way of a first multiway valve 10. The intermediate container 5 that is shown in FIG. 2 also comprises a device 2 for heating up the organometallic starting material 6, a device 3 for cooling down the intermediate container 5 and also a pressure gage 4, the pressure gage 4 being capable of measuring the vapor pressure of the organometallic starting material 6 in the intermediate container 5. In the storage container 1 of FIG. 2, the organometallic starting material 6 is stored at a temperature at which no or largely no disintegration products or decomposition products form.

By opening the first multiway valve 10, the organometallic starting material 6 of the storage container 1 flows into the intermediate container 5. In order to speed up an inflow of the organometallic starting material 6 into the intermediate chamber 5, the intermediate container 5 may be cooled down, in particular by way of the device 3 for cooling down the intermediate container 5, in such a way that the organometallic starting material 6 flows into the intermediate container 5, and for example, condenses, more quickly on account of a difference in temperature occurring between the storage container 1 and the intermediate container 5. Once a partial amount 12 of the organometallic starting material 6 has flowed into the intermediate container, the first multiway valve 10 is closed.

The partial amount 12 of the organometallic starting material 6 is heated up by way of the device 2 for heating up the organometallic starting material 6. In this case, a vapor pressure, working pressure and/or processing pressure of the partial amount 12 of the organometallic starting material 6 that is constant over time and is, for example, greater than the vapor pressure of the organometallic starting material 6 in the storage container 1 occurs. The pressure gage 4 can be used, for example, to check the pressure occurring during the heating up of the partial amount 12 of the organometallic starting material 6. Once the constant-over-time vapor pressure has occurred in the intermediate container 5, the second multiway valve 20 and the fourth multiway valve 40 are opened and the partial amount 12 of the organometallic starting material 6 partially flows as a gas into the process chamber 7 in a pulse-like manner. After the pulse-like inflow of the organometallic starting material 6, the second multiway valve 20 and the fourth multiway valve 40 can be closed.

Furthermore, the pulse-like inflow of the partial amount 12 of the organometallic starting material 6 as a gas can be speeded up, in particular by opening the fifth multiway valve 50, which is connected to the gas-metering element 9. The gas-metering element 9 allows, for example, a carrier gas to be fed to the gaseous organometallic starting material 6.

After the coating cycle, the organometallic starting material 6 that remains in the intermediate container 5 can be directed, sucked or pumped into a collecting chamber 8 by way of opening the third multiway valve 30. The collecting chamber 8, which is connected to the intermediate container 5 by way of the third multiway valve 30, may be connected to a vacuum pump 11. The vacuum pump 11 may be used in particular for pumping the disintegration products or decomposition products of the partial amount 12 of the organometallic starting material 6 out of the intermediate container 5 in a time-efficient manner. It is consequently possible by the ALD coating system 100 described in FIG. 2 to keep the storage container 1 and also the intermediate container 5 free, substantially free, from disintegration products or decomposition products of the organometallic starting material 6.

In particular, the intermediate container 5 may be arranged so close to the process chamber 7 that a conductance of the line is constant or largely constant. Furthermore, the first multiway valve 10 is likewise arranged close to the intermediate container 5, so that the conductance of the line between the first multiway valve 10 and the intermediate container 5 is constant or largely constant.

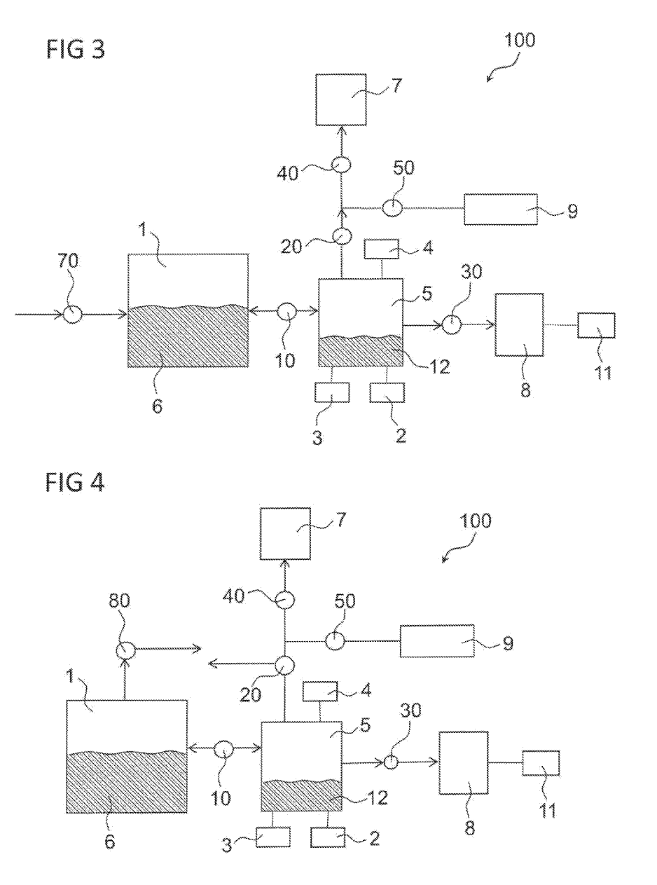

The exemplary embodiment of the ALD coating system 100 shown in FIG. 3 shows the ALD coating system 100 described in conjunction with FIG. 2, with the difference that arranged upstream of the storage container 1 is a seventh multiway valve 70. By way of the seventh multiway valve 70, for example, a further carrier gas can be made to flow into the storage container 1, so that speeded-up feeding of the organometallic starting material 6 from the storage container 1 into the intermediate container 5 can take place. In this case, the seventh multiway valve 70 that is described in conjunction with FIG. 3 is an optional component of the ALD coating systems described here, which may also be present in the further FIGURES described here with regard to the ALD coating system 100.

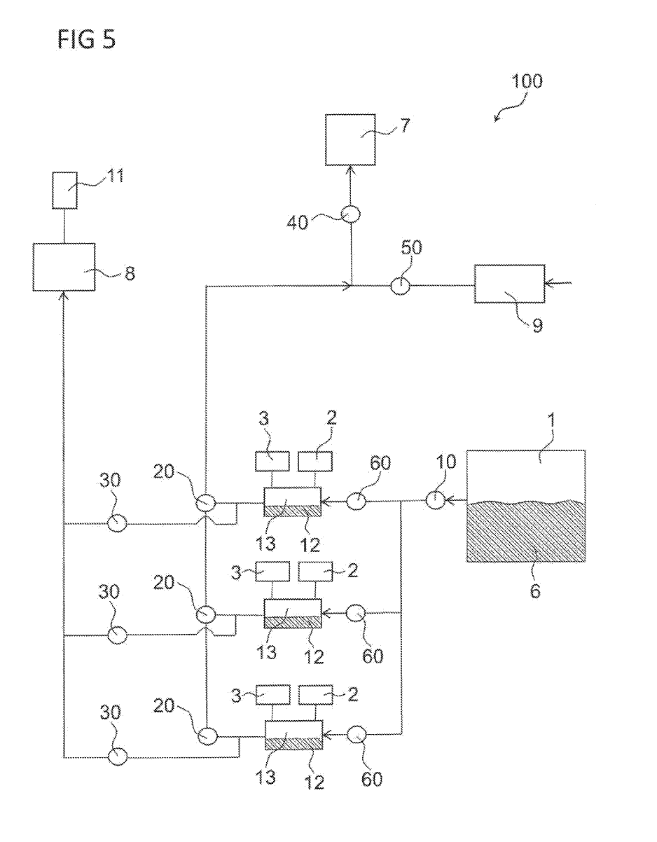

The exemplary embodiment of the ALD coating system 100 shown in FIG. 4 is based in turn on the ALD coating system of FIG. 2, with the difference that the storage container comprises an eighth multiway valve 80, for cleaning the storage container 1. The eighth multiway valve 80 may be used in particular for particularly quick cleaning of the storage container. The intermediate container 5 described here may, however, have the effect of reducing the cleaning processes for the storage container 1, or time intervals between two cleaning processes of the storage container can be increased, since the forming of decomposition products or disintegration products in the storage container 1 can be largely or completely avoided by the ALD coating system 100 described here.

The exemplary embodiment of the ALD coating system shown in FIG. 5 is based on the ALD coating system 100 shown in FIG. 2, with the difference that the intermediate container 5 comprises a multiplicity of individual intermediate chambers 13; the intermediate chambers 13 respectively have the second multiway valve 20 and the third multiway valve 30 and a sixth multiway valve 60, the sixth multiway valves 60 being located between the first multiway valve 10 and the intermediate chambers 13, taken from the storage container. The additional sixth multiway valves 60 shown in FIG. 5 may be intended for the individual filling of the intermediate chambers 13 with the partial amount 12 of the organometallic starting material 6. The filling of the intermediate chambers 13 with the partial amount 12 of the organometallic starting material 6 may take place, for example, one after the other or at the same time by means of the sixth multiway valve 60. The conductance between the sixth multiway valve 60 and the intermediate chambers 13 may be constant or largely constant. The intermediate chambers 13 of the ALD coating system 100 of FIG. 5 respectively have the device for heating up 2 and the device for cooling down 3.

The temperature of the partial amount 12 and/or the partial amount 12 of the organometallic starting material 6 in the intermediate chambers 13 is increased by the device 2 for heating up the organometallic starting material 6 until the vapor pressure required for the coating cycle occurs. The intermediate chambers 13 may be heated up at staggered times. The intermediate chambers 13 may be respectively switched to the process chamber 7 after the opening of the second multiway valve 20 and the fourth multiway valve 40. After depositing the monolayer or the coating cycle, the corresponding second multiway valve 20 is closed and the next second multiway valve 20 is opened. Residual amounts in the intermediate chambers 13 are either sublimated back in the collecting chamber 8 or drawn off or pumped away by way of the third multiway valve 30.

The invention is not restricted by the description on the basis of the exemplary embodiments to these embodiments. Rather, the invention comprises every novel feature and every combination of features, which includes in particular any combination of features in the patent claims, even if this feature or this combination itself is not explicitly specified in the patent claims or exemplary embodiments.

What is claimed is:

1. A method for operating an ALD coating system for growing at least one layer on a substrate, the method comprising:
providing an organometallic starting material in a storage container;
lowering a temperature of an intermediate container by a device for cooling the intermediate container so that a temperature of the intermediate container is below a temperature of the storage container;
flowing a partial amount of the organometallic starting material into the intermediate container;
heating the partial amount of the organometallic starting material by a device for heating the organometallic starting material so that a pressure of the partial amount of the organometallic starting material is constant over time and/or is greater than a pressure of the organometallic starting material in the storage container;
opening a second multiway valve when the pressure is constant over time and/or greater than a pressure of the organometallic starting material in the storage container, so that the partial amount of the organometallic starting material partially flows as a gas into a process chamber in a pulse-like manner, closing the second multiway valve after the pulse-like inflow; and
opening a third multiway valve so that the organometallic starting material that remains in the intermediate container flows away into a collecting chamber,
wherein the temperature of the intermediate container is lowered before the partial amount of the organometallic starting material flows in the intermediate container.

2. The method for operating an ALD coating system according to claim 1, wherein the intermediate container is arranged downstream of the storage container by way of a first multiway valve.

3. The method for operating an ALD coating system according to claim 1, wherein the ALD coating system comprises a pressure gage coupled to the intermediate container, and wherein a conductance of a line between the intermediate container and the process chamber is constant or largely constant.

4. The method for operating an ALD coating system according to claim 2, wherein the ALD coating system comprises a pressure gage coupled to the intermediate container, and wherein a conductance of a line between the first multiway valve and the intermediate container is constant or largely constant.

5. The method for operating an ALD coating system according to claim 1, wherein a fourth multiway valve and a fifth multiway valve are arranged between the second multiway valve and the process chamber, wherein the second multiway valve and the fourth multiway valve are located on the same line to the process chamber, taken from the intermediate container, wherein the fourth multiway valve is arranged downstream of the second multiway valve, wherein the fifth multiway valve is located on a line between the second multiway valve and the fourth multiway valve, and wherein a gas-metering element for feeding a carrier gas and/or purging gas is arranged upstream of the fifth multiway valve.

6. The method for operating an ALD coating system according to claim 2, wherein the intermediate container comprises a plurality of individual intermediate chambers, wherein each intermediate chamber has a second multiway valve, a third multiway valve and a sixth multiway valve, and wherein each sixth multiway valve is located between the first multiway valve and the intermediate chamber, taken from the storage container.

7. The method for operating an ALD coating system according to claim 6, wherein each intermediate chamber has a device for heating and the device for cooling.

8. The method for operating an ALD coating system according to claim 1, wherein the organometallic starting material in the storage container is free or largely free from disintegration products of the organometallic starting material.

9. The method for operating an ALD coating system according to claim 1, wherein the organometallic starting material in the process chamber is free or largely free from disintegration products of the organometallic starting material.

10. The method for operating an ALD coating system according to claim 1, wherein a seventh multiway valve for providing a further carrier gas is arranged upstream of the storage container.

11. The method for operating an ALD coating system according to claim 1, wherein an eighth multiway valve for cleaning the storage container is arranged upstream of the storage container.

12. The method for operating an ALD coating system according to claim 1, wherein the organometallic starting material is a tetrakis(dimethylamino)zirconium.

13. The method for operating an ALD coating system according to claim 1, wherein the intermediate container has a pressure gage.

14. The method for operating an ALD coating system according to claim 1, wherein a vacuum pump is arranged downstream of the collecting chamber.

15. The method for operating an ALD coating system according to claim 1, wherein the storage container solely comprises the organometallic starting material.

16. A method for operating an ALD coating system for growing at least one layer on a substrate, the method comprising:
providing an organometallic starting material in a storage container;
flowing a partial amount of the organometallic starting material into an intermediate container; and
heating the partial amount of the organometallic starting material by a device for heating up the organometallic starting material, so that a pressure of the partial amount of the organometallic starting material is greater than a pressure of the organometallic starting material in the storage container occurs,
wherein, before heating the partial amount of the organometallic starting material, lowering a temperature of the intermediate container by a device for cooling the intermediate container, wherein the device for cooling lowers a temperature of the intermediate container below a temperature of the storage container.

17. The method for operating an ALD coating system according to claim 16, wherein the storage container solely comprises the organometallic starting material.

18. The method for operating an ALD coating system according to claim 16, wherein the organometallic starting material is a tetrakis(dimethylamino)zirconium.

19. A method for operating an ALD coating system for growing at least one layer on a substrate, the method comprising:
providing an organometallic starting material in a storage container;
lowering a temperature of an intermediate container by cooling the intermediate container so that a temperature of the intermediate container is below a temperature of the storage container;
after lowering the temperature, flowing a partial amount of the organometallic starting material into the intermediate container;
heating the partial amount of the organometallic starting material in the intermediate container so that a pressure of the partial amount of the organometallic starting material is constant over time and/or is greater than a pressure of the organometallic starting material in the storage container;
after heating the partial amount, flowing a portion of the partial amount of the organometallic starting material as a gas into a process chamber; and
after flowing the portion into the process chamber, flowing the the organometallic starting material that remains in the intermediate container into a collecting chamber.
